(19) United States
(12) Patent Application Publication
(10) Pub. No.: US 2015/0200241 A1
(43) Pub. Date: Jul. 16, 2015

(54) ORGANIC LIGHT-EMITTING DIODE (OLED) DISPLAY AND METHOD OF DRIVING THE SAME

(71) Applicant: Samsung Display Co., Ltd., Yongin-city (KR)

(72) Inventor: Jung-Bae KIM, Yongin-city (KR)

(21) Appl. No.: 14/593,146

(22) Filed: Jan. 9, 2015

(30) Foreign Application Priority Data
Jan. 13, 2014 (KR) 10-2014-0003716

(51) Int. Cl. H01L 27/32

(52) U.S. Cl. CPC H01L 27/3279; H01L 27/3262; H01L 27/3265

(57) ABSTRACT

An organic light-emitting diode (OLED) display and method of driving the same are disclosed. In one aspect, the OLED display includes a plurality of data lines, a plurality of scan lines intersecting the data lines, and a plurality of pixels respectively arranged at the intersections between the data lines and the scan lines, wherein each pixel includes a differential resistor. The OLED display also includes a plurality of main power lines configured to respectively apply a voltage to the pixels and a plurality of auxiliary power lines intersecting the main power lines. The auxiliary power lines are electrically connected to the main power lines via the differential resistors.

### RELATED APPLICATIONS

This application claims priority to and the benefit of Korean Patent Application No. 10-2014-0003716, filed on Jan. 13, 2014, in the Korean Intellectual Property Office, the entire contents of which are incorporated herein by reference in their entirety.

### BACKGROUND

1. Field

The described technology generally relates to an organic light-emitting diode (OLED) display and a method of driving the same.

2. Description of the Related Technology

Recently, various types of flat panel displays (FPDs) have been developed which have a light weight and low volume when compared to cathode ray tubes.

One type of flat panel display is an organic light-emitting diode (OLED) display. OLED displays are self-emissive and typically have excellent luminance and color purity. Due to these and other favorable qualities, OLED displays are generally regarded as next-generation displays.

OLED displays can be categorized into passive matrix OLED (PMOLED) displays and active matrix OLED (AMOLED) displays based on their driving technique.

In AMOLED displays, a plurality of pixels are arranged in a matrix formed at the intersections between scan and data lines and each pixel or sub-pixel is connected to one of the scan lines and one of the data lines. The emission of an OLED included in each pixel is controlled using thin film transistors and capacitors based on signals received from the scan and data lines.

A first power source ELVDD as a pixel power source is applied to a first electrode (anode electrode) of the OLED and a second power source ELVSS is applied to a second electrode (cathode electrode) of the OLED. The luminance of each pixel is determined according to the amount of current flowing from the first electrode to the second electrode of the OLED.

### SUMMARY OF CERTAIN INVENTIVE ASPECTS

One inventive aspect is an OLED display including power lines arranged in a mesh-type structure including main power lines supplying a first power source as a pixel power source to each pixel and auxiliary power lines arranged to intersect the main power lines, a differential resistor is formed in each pixel connected to the main power lines, and the auxiliary power lines are formed to be connected to the main power lines via the differential resistors, so that a voltage drop with respect to the power lines can be prevented.

Another aspect is an OELD display including an image display unit including a plurality of data lines arranged in a first direction, a plurality of scan lines arranged in a second direction, and a plurality of pixels respectively arranged at intersection portions of the data lines and the scan lines, a plurality of main power lines configured to supply a first power source as a pixel power source to each pixel, and a plurality of auxiliary power lines arranged to intersect the main power lines, and a differential resistor formed in each pixel, wherein the auxiliary power lines are connected to the main power lines via the differential resistor provided in each pixel.

Each pixel may include a first transistor including a gate connected to a first node, a source connected to a second node, and a drain connected to an anode electrode of an OLED, a second transistor including a gate connected to a scan line, a source connected to a data line, and a drain connected to the first node, and a differential resistor formed between the second node and a main power line supplying the first power source to the pixel.

The pixel may further include a capacitor connected between the first and second nodes or a capacitor connected between the first node and the main power line.

The auxiliary power lines may be connected to the second nodes of the pixels arranged on each horizontal line corresponding thereto.

The auxiliary power lines may be connected to the main power lines via the differential resistors in the pixels arranged for each horizontal line.

The resistance of the differential resistor may be changed for each horizontal line. The resistance of the differential resistor may be differently set depending on a distance of the differential resistor from a pad portion of the image display unit.

The resistance of the differential resistor may be designed to be increased as the horizontal line is closer to the pad portion.

The differential resistor may include a thin film transistor. The resistance of the differential resistor may be set by controlling the ratio of the width and the length of an active layer of the thin film transistor.

The differential resistors provided in the pixels arranged on the same horizontal lines may have the same resistance.

Another aspect is an OLED display including a plurality of data lines, a plurality of scan lines intersecting the data lines, a plurality of pixels respectively arranged at the intersections between the data lines and the scan lines, wherein each pixel includes a differential resistor, a plurality of main power lines configured to respectively apply a voltage to the pixels, and a plurality of auxiliary power lines intersecting the main power lines, wherein the auxiliary power lines are electrically connected to the main power lines via the differential resistors.

Each pixel can include an OLED, a first transistor including a gate electrically connected to a first node, a source electrically connected to a second node, and a drain electrically connected to the OLED, and a second transistor including a gate electrically connected to one of the scan lines, a source electrically connected to one of the data lines, and a drain electrically connected to the first node, wherein the differential resistor of each pixel is electrically connected between the corresponding second node and the corresponding main power line. Each of the pixels can further include a capacitor electrically connected between the first and second nodes. Each of the pixels can further include a capacitor electrically connected between the first node and the corresponding main power line. The auxiliary power lines can be electrically connected to the second nodes of the corresponding pixels. The auxiliary power lines can be electrically connected to the intersecting main power lines via the corresponding differential resistors. The pixels can be arranged in rows and columns and the resistance of the differential resistors of the pixels arranged in different rows are not the same. The OLED display can further include a pad portion electrically connected to the main power lines, wherein the resistance of each of the differential resistors is selected based at least in part on the distance of the differential resistor from the pad portion. The resistance of each of the differential resistors can increase as the distance of the differential resistor to the pad portion decreases. Each of the differential resistors can include a thin film transistor. Each of the thin film transistors can include an active layer and the resistance of each of the differential resistors can be defined based at least partially on the ratio of the width to the length of the active layer. The differential resistors of the pixels arranged in the same row can have substantially the same resistance.

Another aspect is an OLED display including a plurality of pixels arranged in rows and columns, wherein each pixel includes a differential resistor, a plurality of main power lines configured to respectively supply a voltage to the pixels, and a plurality of auxiliary power lines electrically connected to the main power lines via the differential resistors.

The auxiliary power lines can intersect the main power lines, wherein the pixels are respectively arranged at the intersections between the main power lines and the auxiliary power lines, and wherein each of the auxiliary power lines is connected to the intersecting main power lines via the differential resistors of the corresponding pixels. Each of the pixels can further include a driving transistor including a source electrode and the source electrodes of each of the driving transistors can be electrically connected to the corresponding main power lines via the corresponding driving transistor. Each of the pixels can further include a capacitor electrically connected between a gate of the corresponding driving transistor and the corresponding main power line and wherein the source of the driving transistor is electrically connected to the corresponding auxiliary power line. Each of the pixels can further include a capacitor electrically connected between a gate and the source of the corresponding driving transistor and the source of the driving transistor can be electrically connected to the corresponding auxiliary power line. The resistance of the differential resistors of the pixels arranged in different rows are not the same and the differential resistors of the pixels arranged in the same row can have substantially the same resistance. The OLED display can further include a pad portion electrically connected to the main power lines, wherein the resistance of each of the differential resistors is defined based at least in part on the distance of the differential resistor from the pad portion. The resistance of each of the differential resistors can increase as the distance of the differential resistor to the pad portion decreases.

### BRIEF DESCRIPTION OF THE DRAWINGS

FIG. 1 is a schematic block diagram of an OLED display device according to an embodiment.

FIG. 2 is a circuit diagram illustrating the configuration of an embodiment of the pixels shown in FIG. 1.

FIG. 3 is a circuit diagram illustrating the configuration of another embodiment of the pixels shown in FIG. 1.

FIG. 4 is a circuit diagram illustrating the configuration of still another embodiment of the pixels shown in FIG. 1.

### DETAILED DESCRIPTION OF CERTAIN INVENTIVE EMBODIMENTS

The first power source ELVDD is supplied as a constant voltage to each of the pixels and is applied through a plurality of power lines connected to the pixels. However, the first power source ELVDD may not be uniformly applied for to each pixel due to a voltage drop across the power lines. That is, the luminance of pixels positioned farther from a pad portion where the first power source ELVDD is applied is lower than that of pixels positioned closer to the pad portion. Accordingly, the luminance of the entire display panel is non-uniform due to the power loss over the power lines.

This effect is magnified as the size of OLED displays increases since the length of the power lines correspondingly increase. Therefore, the non-uniformity of the luminance due to the voltage drop along the power lines is more noticeable for larger OLED displays.

Exemplary embodiments will now be described more fully hereinafter with reference to the accompanying drawings; however, the described technology can be embodied in different forms and should not be construed as limited to the embodiments set forth herein. Rather, these embodiments are provided so that this disclosure will be thorough and complete, and will fully convey the scope of the embodiments to those skilled in the art.

In the drawings, the dimensions of elements or components may be exaggerated for the sake of clarity. It will be understood that when an element is referred to as being “between” two elements, it can be the only element between the two elements, or one or more intervening elements may also be present. Like reference numerals refer to like elements throughout.

Hereinafter, certain exemplary embodiments of the described technology will be described with reference to the accompanying drawings. Here, when a first element is described as being connected to a second element, the first element may be not only directly connected to the second element but may also be indirectly connected to the second element via a third element. Further, some of the elements that are not essential to the complete understanding of the described technology are omitted for the sake of clarity. The term “substantially” as used in this disclosure can include the meaning of completely, almost completely, or to any significant degree in some applications and in accordance with the understanding of those skilled in the art.

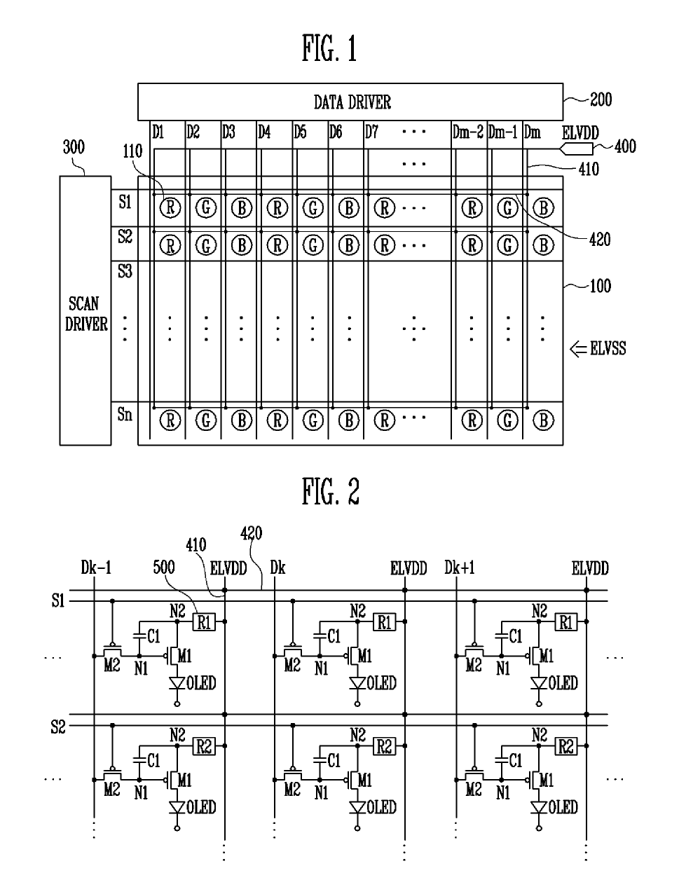

Referring to FIG. 1, the organic light-emitting diode (OLED) display includes an image display unit or display panel 100 configured to display images, a data driver 200 configured to supply data signals, and a scan driver 300 configured to supply scan signals.

The image display unit 100 includes a plurality of scan lines S1, S2, . . . , and Sn arranged in a row direction, a plurality of data lines D1, D2, . . . , Dm−1 and Dm, and a plurality of pixels 110 respectively arranged at the intersections between the data lines and the scan lines. The pixels 110 each include an OLED and a pixel circuit. The image display unit 100 also includes a plurality of main power lines 410 configured to supply a first power source or first voltage ELVDD as a pixel power source to the pixels 110. A second power source or second voltage ELVSS having a potential lower than that of the first power source ELVDD is applied to the image display unit 100.

The image display unit 100 further includes a power supply unit 400 configured to supply the first power source ELVDD to the main power lines 410. In other embodiments, the power supply unit 400 is separated from the image display unit 100.

The first power source ELVDD is a high-potential voltage applied to the pixels 110. The first power source ELVDD is applied through the main power lines 410 connected to the pixels. However, the first power source ELVDD may not be uniformly applied to each of the pixels due to a voltage drop (IR drop) generated in the main power line 410 as the pixels are located farther away from the power supply unit 400.

For example, when the first power source ELVDD supplied from the power supply unit 400 is applied through a pad portion (not shown) formed at an upper portion of the image display unit 100, the luminance of pixels positioned farther from the pad portion is lower than that of pixels positioned closer to the pad portion. Consequently, the luminance of the entire image display unit 100 becomes non-uniform.

That is, the pixels positioned farther from the pad portion to which the first power source ELVDD is applied experience a larger voltage drop due to the length of the power line when compared to the pixels positioned closer to the pad portion. Thus, the amplitude of the first power source ELVDD is less at the pixels positioned farther away, and therefore, the current applied to the OLED of each pixel is altered from the ideal current due to the change in amplitude. As a result, a difference in the luminance of the pixels is generated based on their positioning in the image display unit 100.

According to the embodiment of FIG. 1, in order to overcome such a disadvantage, the image display unit 100 further includes auxiliary power lines 420 electrically connected to the main power lines 410.

As shown in FIG. 1, the power supply unit 400 is implemented with one power supply unit, however, in other embodiments, the power supply unit 400 can be implemented with a plurality of power supply units. The same first power source ELVDD can be supplied to the main power lines 410 at several sides of the image display unit 100 through the power supply units 400. Alternatively, the same first power source ELVDD can be supplied separately to the main power lines 410 and the auxiliary power lines 420 through the power supply units 400.

Returning to the embodiment of FIG. 1, the power lines 410 and 420 through which the first power source ELVDD is applied to the pixels is formed in a mesh-type structure. The mesh-type structure, as shown in FIG. 1, includes the main power lines 410 arranged in a first direction (e.g., the column direction), and the auxiliary power lines 420 arranged in a second direction (e.g., the row direction) intersecting the first direction.

In the embodiment shown in FIG. 1, the main power lines 410 are arranged substantially parallel to the data lines D1 to Dm and the auxiliary power lines 420 are arranged substantially parallel to the scan lines S1 to Sn.

The main power lines 410 can be formed of the same metal material and in the same layer as the data lines D1 to Dm and the auxiliary power lines 420 can be formed of the same metal material and in the same layer as the scan lines S1 to Sn. Since the resistance of the metal material forming the scan lines S1 to Sn is generally higher than that of the metal material forming the data lines D1 to Dm, the resistance in the second direction, in which the auxiliary power lines 420 are arranged, is greater than that of the main power lines 410. Consequently, the current of the first power source ELVDD applied to the auxiliary power lines 420 does not uniformly flow when compared to current flowing in the first direction via the main power lines 410. Accordingly, although the power lines are configured in a mesh-type structure, the voltage drop with along the power lines may not be sufficiently reduced.

Particularly, when the pixels are digitally driven and include a basic pixel circuit including two transistors and one capacitor, the first power source ELVDD can be directly applied to the OLED included in each pixel so that the luminance of each pixel is determined. Therefore, the resulting difference in luminance between the pixels can be attributed to the voltage drop along the power lines 410 and 420.

Accordingly, in some embodiments, a differential resistor 500 is included in each pixel, in order to minimize the change in current applied to the OLED of each pixel. This will be described in detail with reference to the embodiments of FIGS. 2 to 4.

FIG. 2 illustrates pixels arranged on first and second scan lines among the pixels shown in FIG. 1. Each pixel has a pixel structure including two transistors and one capacitor and is driven digitally. However, the described technology is not limited to the illustrated pixel configuration.

Referring to FIG. 2, the pixels are respectively connected to the scan lines and the data lines. The main power lines 410 supply the first power source ELVDD as a pixel power source to each pixel and the auxiliary power lines 420 are electrically connected to the main power lines 410 so to as to form a mesh-type structure.

The mesh-type structure, as shown in FIG. 2, includes the main power lines 410 arranged in the first direction (e.g., the column direction) and the auxiliary power lines 420 electrically connected to the main power lines 410. The auxiliary power lines 420 are arranged in the second direction (e.g., the row direction) intersecting the first direction.

Each pixel, as shown in FIG. 2, includes a pixel circuit and an OLED. The pixel circuit includes a first transistor M1, a second transistor M2, and a capacitor C1. Each of the first and second transistors M1 and M2 include a source, a drain, and a gate. The capacitor C1 includes a first electrode and a second electrode.

In the embodiment shown in FIG. 2, a differential resistor 500 is further formed in each pixel.

The gate of the first transistor M1 is connected to a first node N1 and the source of the first transistor M1 is connected to a second node N2. The drain of the first transistor M1 is connected to an anode electrode of the OLED.

In the FIG. 2 embodiment, the differential resistor 500 is formed between the second node N2 and the main power line 410 supplying the first power source ELVDD to the pixel. That is, the source of the first transistor M1 is electrically connected to the main power line 410 supplying the first power source ELVDD to the pixel via the differential resistor 500. The first node N1 is connected to the drain of the second transistor M2.

The first transistor M1 supplies a current corresponding to a data signal to the OLED. Here, the second power source ELVSS is connected to a cathode electrode of the OLED.

The source of the second transistor M2 is connected to the data line D and the drain of the second transistor M2 is connected to the first node N1. The gate of the second transistor M2 is connected to the scan line S. The data signal is supplied to the first node N1 according to a scan signal applied to the gate of the second transistor M2.

The capacitor C1 is connected between the first and second nodes N1 and N2.

That is, the first electrode of the capacitor C1 is connected to the gate of the first transistor M1 and the second electrode of the capacitor C1 is connected to the second node N2, so that the capacitor C1 is electrically connected to the main power line 410 supplying the first power source ELVDD via the differential resistor 500.

The capacitor C1 stores an electric charge according to the data signal applied to the pixel. A signal is applied to the gate of the first transistor M1 based on the charge stored in the capacitor C1 for one frame, so that the operation of the first transistor M1 is maintained over the one frame.

However, although the power lines are configured in the mesh-type structure as described above, the voltage drop over the power lines may not be sufficiently reduced.

Accordingly, in the embodiment of FIG. 2, the source of the first transistor M1, i.e., the second node N2 is not directly connected to the main power line 410 supplying the first power source ELVDD to the pixel. Instead, the differential resistor 500 is formed between the second node N2 and the main power line 410. Thus, it is possible to reduce the variation in current applied to the OLED of each pixel based on the position of the pixel within the image display unit 100.

In this embodiment, the differential resistor 500 compensates for a voltage drop of the main power line 410. To this end, the resistance of the differential resistor 500 is changed for each horizontal line.

For example, when the first power source ELVDD is supplied through the pad portion (not shown) provided at the upper portion of the image display unit 100, the resistance R1 of the differential resistor 500 provided in each pixel formed on the first horizontal line, which receives the least influence of the voltage drop of the main power line 410, is greater than that of the differential resistor 500 provided in each pixel formed on subsequent horizontal lines (R1>R2>R3> . . . ).

As such, the pixels are designed so that the resistance of the differential resistor 500 is changed for each horizontal line, so that it is possible to maintain the first power source ELVDD at a substantially constant level applied to the driving transistor M1 in each pixel of the image display unit 100. Accordingly, it is possible to compensate for a voltage drop that increases as the length of the main power line increases.

The differential resistor 500 may be formed using poly-silicon (poly-Si), a transparent conductive layer (e.g., ITO), a metal, a thin film transistor (TFT), etc.

However, in order to compensate for the voltage drop, using the differential resistor 500 as described above, the differential resistors 500 provided in the same horizontal line necessarily have substantially the same resistance.

That is, all the pixels arranged in the first horizontal line have substantially the same resistance R1 of the first differential resistor 500 and all the pixels arranged in the second horizontal line have substantially the same resistance R2 of the second differential resistor 500, which is less than the resistance R1.

However, the resistance of the differential resistor 500 formed in the pixels may vary depending on manufacturing variances or the like. Differences in the resistance between the differential resistors 500 can be caused by the material used for the resistor.

For example, when poly-silicon (poly-Si) is used, the differential resistor 500 is formed by forming the poly-silicon in the shape of a line. However, if poly silicon is formed in a line, a processing error in the range of about 10% to about 25% may occur.

The difference in resistance between the differential resistors 500 generates a difference in voltage between the pixels formed in the same horizontal line, which causes a change in current applied to the OLED of each pixel. As a result, the luminance of the entire image display unit may become non-uniform.

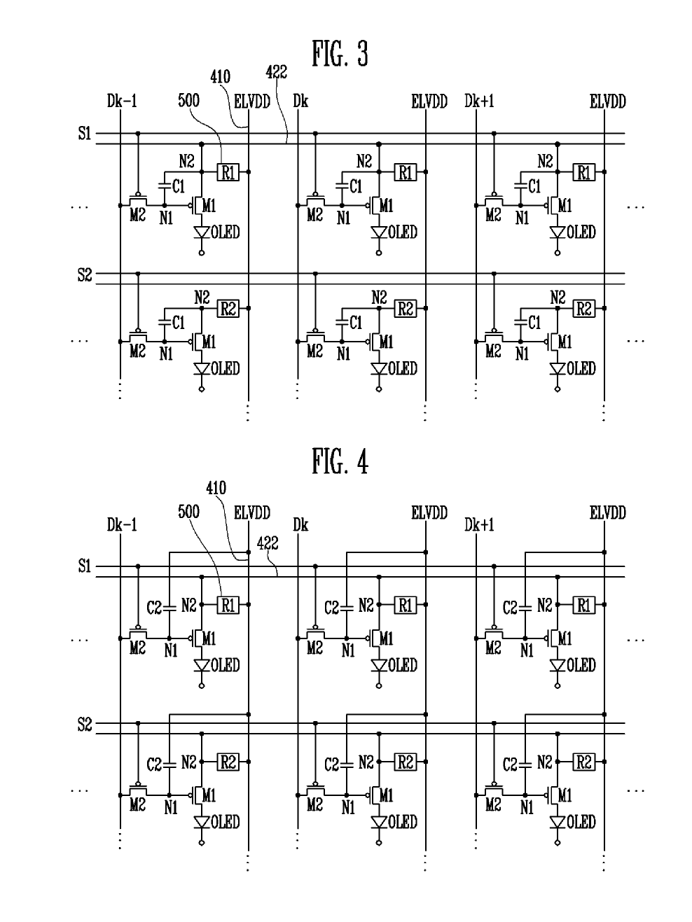

In order to overcome this disadvantage, in the main and auxiliary power lines 410 and 420 formed into the mesh-type structure, the differential resistor 500 is formed in each pixel connected to the power lines and the auxiliary power lines are formed to be connected to the main power lines 410 via the differential resistors 500. This will be described in detail with reference to the embodiments of FIGS. 3 and 4.

FIGS. 3 and 4 illustrate pixels arranged on the first and second horizontal lines among the pixels shown in FIG. 1. Each pixel has a pixel structure including two transistors and one capacitor and is digitally driven. However, the described technology is not limited to the configuration of the pixels according to these embodiments.

The embodiment shown in FIG. 3 is identical to that shown in FIG. 2 except for the connection of the auxiliary power lines 420. The embodiment shown in FIG. 4 is identical to that shown in FIG. 3 except for the connection of the capacitor C2. Therefore, components identical to those of the aforementioned embodiment are designated by like reference numerals and their detailed descriptions will be omitted.

Referring to FIGS. 3 and 4, the pixels are respectively connected to the scan lines, the data lines, and the main power lines 410 supplying the first power source ELVDD as a pixel power source to each pixel. The auxiliary power lines 422 are electrically connected to the main power lines 410 are formed in a mesh-type structure.

The mesh-type structure, as shown in FIGS. 3 and 4, includes the main power lines 410 arranged in the first direction (e.g., the column direction) and the auxiliary power lines 422 electrically connected to the main power lines 410. The auxiliary power lines 422 are arranged in the second direction (e.g., the row direction) intersecting the first direction.

In the embodiments of FIGS. 3 and 4, the auxiliary power lines 422 are not directly connected to the main power lines 410, but are connected to the main power lines 410 via a differential resistor 500 provided in each pixel.

Each pixel, as shown in FIGS. 3 and 4, includes the pixel circuit and the OLED. The pixel circuit includes the first transistor M1, the second transistor M2, and a capacitor C1 or C2. Each of the first and second transistors M1 and M2 includes a source, drain, and gate. The capacitors C1 and C2 each include first and second electrodes.

The gate of the first transistor M1 is connected to the first node N1 and the source of the first transistor M1 is connected to the second node N2. The drain of the first transistor M1 is connected to the anode electrode of the OLED.

In these embodiments, the differential resistor 500 is formed between the second node N2 and the main power line 410 supplying the first power source ELVDD to the pixel. That is, the source of the first transistor M1 is electrically connected to the main power line 410 supplying the first power source ELVDD to the pixel via the differential resistor 500.

The first transistor M1 supplies a current corresponding to a data signal to the OLED. Here, the second power source ELVSS is connected to the cathode electrode of the OLED.

The source of the second transistor M2 is connected to the data line D and the drain of the second transistor M2 is connected to the first node N1. The gate of the second transistor M2 is connected to the scan line S. The data signal is supplied to the first node N1 according to a scan signal applied to the gate of the second transistor M2.

The capacitor C1 is connected between the first and second nodes N1 and N2. The capacitor C2 is connected between the first node N1 and the main power line 410.

In the embodiment of FIG. 3, the first electrode of the capacitor C1 is connected to the gate of the first transistor M1 operated as the driving transistor and the second electrode of the capacitor C1 is connected to the second node N2, so that the capacitor C1 is electrically connected to the main power line 410 supplying the first power source ELVDD via the differential resistor 500.

On the other hand, in the embodiment of FIG. 4, the first electrode of the capacitor C2 is connected to the gate of the first transistor M1 operated as the driving transistor and the second electrode of the capacitor C2 is directly connected to the main power line 410 supplying the first power source ELVDD.

The differential resistor 500 compensates for a voltage drop of the main power line 410. To this end, the resistance of the differential resistor 500 is varied for each horizontal line.

For example, when the first power source ELVDD is supplied through the pad portion (not shown) provided at the upper portion of the image display unit 100, the resistance R1 of the differential resistor 500 provided in each pixel formed on the first horizontal line, which receives the least influence of the voltage drop of the main power line 410, is greater than that of the differential resistor 500 provided in each pixel formed on subsequent horizontal lines (R1>R2>R3> . . . ).

As such, the pixels are designed so that the resistance of the differential resistor 500 is changed for each horizontal line, so that it is possible to maintain the first power source ELVDD at a substantially constant level applied to the driving transistor M1 provided in each pixel of the image display unit 100. Accordingly, it is possible to compensate for a voltage drop that increases as the length of the main power line 4100 increases.

The differential resistor 500 can be formed using poly-silicon (poly-Si), a transparent conductive layer (e.g., ITO), a metal, a thin film transistor (TFT), etc. Particularly, when the TFT is used, the resistance of the differential resistor 500 can be set by controlling the ratio of width (W)/length (L) of an active layer of the TFT.

However, in order to compensate for the voltage drop, using the differential resistor 500 as described above, the differential resistors 500 provided for each horizontal line have substantially the same resistance.

That is, all the pixels arranged on the first horizontal line have substantially the same resistance R1 of the first differential resistor 500 and all the pixels arranged on the second horizontal line have substantially the same resistance R2 of the second differential resistor 500, which is less than the resistance R1.

However, the resistance of the differential resistor 500 formed in the pixels may vary depending on manufacturing variances or the like. Differences in the resistance between the differential resistors 500 can be caused by the material used for the resistor. In addition, the difference in resistance between the differential resistors 500 causes a difference in voltage between the pixels formed on the same horizontal lines.

In the embodiments of FIGS. 3 and 4, in order to overcome this disadvantage, the auxiliary power lines 422 formed in the mesh-type structure are not directly connected to the main power lines 410, but are connected to the main power lines 410 via the differential resistor 500 provided in each pixel.

That is, in the embodiments of FIGS. 3 and 4, the auxiliary power lines 422 are connected to the second node N2, i.e., the source of the first transistor M1, of each pixel arranged on the horizontal lines corresponding thereto.

For example, the first auxiliary power 422 line, arranged substantially parallel to the first scan line S1, is connected to the second nodes N2 of the pixels arranged in the first horizontal line. Similarly, the second auxiliary power line, arranged substantially parallel to the second scan line S2, is connected to the second nodes N2 of the pixels arranged in the second horizontal line.

The differential resistor 500 is formed between the second node N2 of each pixel and the main power line 410 supplying the first power source ELVDD to each pixel, and thus the auxiliary power lines 422 are connected to the main power lines 410 via the differential resistors 500 provided in the pixels arranged for each horizontal line.

The auxiliary power lines 422 are respectively connected to all of the pixels in each horizontal line. Thus, although there is a difference in resistance between the differential resistors 500 in the pixels arranged on the same horizontal line, it is possible to compensate for these differences.

That is, the auxiliary power lines 422 connect the second nodes N2 of the pixels for each horizontal line and the source of the first transistor M1 of each pixel arranged on the same horizontal line is connected to the second node N2. Thus, the voltage of the source of the first transistor M1 of each pixel is substantially constant along the same horizontal line, regardless of the difference in resistance between the differential resistors 500.

According to the embodiments of FIGS. 3 and 4, the differential resistors 500 are formed in each pixel, so that it is possible to compensate for a voltage drop of the main power lines 410 supplying the first power source ELVDD to each pixel. In addition, the auxiliary power lines 422 are formed to be connected to the main power lines 410 via the differential resistor 500 of each pixel arranged on the same horizontal line, so that the non-uniformity of the luminance of the entire image display unit caused by the difference in resistance between the differential resistors 500 can be prevented.

Exemplary embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting diode (OLED) display, comprising:
a plurality of data lines;
a plurality of scan lines intersecting the data lines;
a plurality of pixels respectively arranged at the intersections between the data lines and the scan lines, wherein each pixel includes a differential resistor;
a plurality of main power lines configured to respectively apply a voltage to the pixels; and
a plurality of auxiliary power lines intersecting the main power lines,
wherein the auxiliary power lines are electrically connected to the main power lines via the differential resistors.

2. The OLED display of claim 1, wherein each pixel includes:
an OLED;
a first transistor including i) a gate electrically connected to a first node, ii) a source electrically connected to a second node, and iii) a drain electrically connected to the OLED; and
a second transistor including i) a gate electrically connected to one of the scan lines, ii) a source electrically connected to one of the data lines, and iii) a drain electrically connected to the first node,
wherein the differential resistor of each pixel is electrically connected between the corresponding second node and the corresponding main power line.

3. The OLED display of claim 2, wherein each of the pixels further includes a capacitor electrically connected between the first and second nodes.

4. The OLED display of claim 2, wherein each of the pixels further includes a capacitor electrically connected between the first node and the corresponding main power line.

5. The OLED display of claim 2, wherein the auxiliary power lines are electrically connected to the second nodes of the corresponding pixels.

6. The OLED display of claim 5, wherein the auxiliary power lines are electrically connected to the intersecting main power lines via the corresponding differential resistors.

7. The OLED display of claim 2, wherein the pixels are arranged in rows and columns and wherein the resistance of the differential resistors of the pixels arranged in different rows are not the same.

8. The OLED display of claim 7, further comprising a pad portion electrically connected to the main power lines, wherein the resistance of each of the differential resistors is selected based at least in part on the distance of the differential resistor from the pad portion.

9. The OLED display of claim 8, wherein the resistance of each of the differential resistors increases as the distance of the differential resistor to the pad portion decreases.

10. The OLED display of claim 1, wherein each of the differential resistors comprises a thin film transistor.

11. The OLED display of claim 10, wherein each of the thin film transistors comprises an active layer and wherein the resistance of each of the differential resistors is defined based at least partially on the ratio of the width to the length of the active layer.

12. The OLED display of claim 7, wherein the differential resistors of the pixels arranged in the same row have substantially the same resistance.

13. An organic light-emitting diode (OLED) display, comprising:
a plurality of pixels arranged in rows and columns, wherein each pixel includes a differential resistor;
a plurality of main power lines configured to respectively supply a voltage to the pixels; and
a plurality of auxiliary power lines electrically connected to the main power lines via the differential resistors.

14. The OLED display of claim 13, wherein the auxiliary power lines intersect the main power lines, wherein the pixels are respectively arranged at the intersections between the main power lines and the auxiliary power lines, and wherein each of the auxiliary power lines is connected to the intersecting main power lines via the differential resistors of the corresponding pixels.

15. The OLED display of claim 14, wherein each of the pixels further comprises a driving transistor including a source electrode and wherein the source electrodes of each of the driving transistors is electrically connected to the corresponding main power lines via the corresponding driving transistor.

16. The OLED display of claim 15, wherein each of the pixels further comprises a capacitor electrically connected between a gate of the corresponding driving transistor and the corresponding main power line and wherein the source of the driving transistor is electrically connected to the corresponding auxiliary power line.

17. The OLED display of claim 15, wherein each of the pixels further comprises a capacitor electrically connected between a gate and the source of the corresponding driving transistor and wherein the source of the driving transistor is electrically connected to the corresponding auxiliary power line.

18. The OLED display of claim 13, wherein the resistance of the differential resistors of the pixels arranged in different rows are not the same and wherein the differential resistors of the pixels arranged in the same row have substantially the same resistance.

19. The OLED display of claim 13, further comprising a pad portion electrically connected to the main power lines, wherein the resistance of each of the differential resistors is defined based at least in part on the distance of the differential resistor from the pad portion.

20. The OLED display of claim 19, wherein the resistance of each of the differential resistors increases as the distance of the differential resistor to the pad portion decreases.
